(19) United States
(12) Patent Application Publication
(10) Pub. No.: US 2023/0387195 A1
(43) Pub. Date: Nov. 30, 2023

(54) FIELD TERMINATION STRUCTURE FOR MONOLITHICALLY INTEGRATED POWER SEMICONDUCTOR DEVICES

(71) Applicant: Infineon Technologies AG, Neubiberg (DE)

(72) Inventors: Kwok-Wai Ma, Singapore (SG); Frank Dieter Pfirsch, Muenchen (DE)

(21) Appl. No.: 17/751,909

(22) Filed: May 24, 2022

(51) Int. Cl. H01L 29/06; H01L 29/40

(52) U.S. Cl. CPC H01L 29/0623; H01L 29/404

(57) ABSTRACT

A semiconductor die includes: a semiconductor substrate; power semiconductor devices formed in the semiconductor substrate; and a field termination structure interposed between adjacent ones of the power semiconductor devices and between the power semiconductor devices and an edge of the semiconductor substrate. The field termination structure includes: a first part that is designed for a bidirectional electric potential gradient during operation of the power semiconductor devices and configured to prevent a space charge region that arises in one power semiconductor device from reaching an adjacent power semiconductor device under both directions of the bidirectional electric potential gradient; and a second part that is designed for a unidirectional electric potential gradient during operation of the power semiconductor devices and configured to prevent a space charge region that arises in a power semiconductor device from reaching the edge of the semiconductor substrate under a single direction of the unidirectional electric potential gradient.

### BACKGROUND

Power semiconductor devices such as IGBTs (insulated gate bipolar transistors), power MOSFETs (metal-oxide-semiconductor field-effect transistors), JFETs (junction field-effect transistors), HEMTs (high electron mobility transistors), power diodes, etc. require a field termination structure outside the device active/cell area. The field termination structure minimizes electric field (E-field) enhancement around the edge of the device, so that the breakdown voltage can approach the ideal parallel plane value. For example, in reverse blocking IGBTs, field termination structures are needed for blocking the full rated voltage in both directions. In this case, the field termination structure is located between the IGBT cell field and the edge of the die (chip).

Field termination is a necessary part of high-voltage power semiconductor device design but does not participate in the active function of the device. The area required for field termination is in addition to the active area needed to implement the active device function and thus reduces the die area utilization ratio and is therefore considered overhead compared to the active area. Since the required die area for field termination is reduced by a lesser extent than the active area when the device current rating is reduced, the area utilization ratio is further reduced as current rating decreased. This leads to unfavorable cost-effectiveness for power semiconductor devices having a low current rating. Field termination design is further complicated by monolithically integrating different power semiconductor devices.

Thus, there is a need for an improved field termination for power semiconductor devices.

### SUMMARY

According to an embodiment of a semiconductor die, the semiconductor die comprises: a semiconductor substrate; a plurality of power semiconductor devices formed in the semiconductor substrate and sharing one or more common doped regions that form a common power terminal at a first side of the semiconductor substrate, wherein at a second side of the semiconductor substrate opposite the first side, each power semiconductor device has an individual power terminal that is electrically coupled to one or more individual doped regions that are isolated from the other power semiconductor devices; and a field termination structure that separates the one or more individual doped regions of the power semiconductor devices from one another and from an edge of the semiconductor substrate, wherein the field termination structure comprises: a first part designed for a bidirectional electric potential gradient during operation of the power semiconductor devices and configured to prevent a space charge region that arises in one power semiconductor device from reaching an adjacent power semiconductor device under both directions of the bidirectional electric potential gradient; and a second part designed for a unidirectional electric potential gradient during operation of the power semiconductor devices and configured to prevent a space charge region that arises in one power semiconductor device from reaching an edge of the semiconductor substrate under a single direction of the unidirectional electric potential gradient. For example, the second part is designed to prevent the space charge region that arises in one power semiconductor device from reaching the edge of the semiconductor substrate only under a single direction of the unidirectional electric potential gradient but not in the opposite direction.

According to another embodiment of a semiconductor die, the semiconductor die comprises: a semiconductor substrate; a plurality of power semiconductor devices formed in the semiconductor substrate; and a field termination structure interposed between adjacent ones of the power semiconductor devices and between the power semiconductor devices and an edge of the semiconductor substrate, wherein the field termination structure comprises: a first part designed for a bidirectional electric potential gradient during operation of the power semiconductor devices and configured to prevent a space charge region that arises in one power semiconductor device from reaching an adjacent power semiconductor device under both directions of the bidirectional electric potential gradient; and a second part designed for a unidirectional electric potential gradient during operation of the power semiconductor devices and configured to prevent a space charge region that arises in a power semiconductor device from reaching the edge of the semiconductor substrate under a single direction of the unidirectional electric potential gradient.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a partial cross-sectional view of a semiconductor die having a field termination structure for power semiconductor devices monolithically integrated in the die.

FIG. 2 is a schematic diagram of a 3-phase inverter bridge that may be implemented by the power semiconductor devices monolithically integrated in the semiconductor die.

FIG. 3A is a schematic diagram of an H-bridge inverter that may be implemented by the power semiconductor devices monolithically integrated in the semiconductor die.

FIG. 3B is a schematic diagram of a bi-directional controllable switch that may be implemented by the power semiconductor devices monolithically integrated in the semiconductor die.

FIGS. 4 through 9 illustrate respective schematic comparisons of different types of conventional power electronics circuits implemented using separate transistor and/or diode dies, and the semiconductor die of FIG. 1 in which the same functionality is monolithically integrated in a single die or a subset of the dies needed for the conventional implementation.

FIG. 10 is a schematic top plan view of the semiconductor die of FIG. 1 during different operating states.

FIG. 11 is a diagram of three electric potential distributions in different parts of the field termination structure.

FIG. 12 is a top plan view of the semiconductor die of FIG. 1 and shows the field termination structure for three power semiconductor devices.

FIG. 13 is a partial cross-sectional view of the field termination structure in a region between two adjacent power semiconductor devices, according to an embodiment.

FIG. 14 is a partial cross-sectional view of the field termination structure in a region between two adjacent power semiconductor devices, according to another embodiment.

FIG. 15 is a partial cross-sectional view of the field termination structure in a region between two adjacent power semiconductor devices, according to another embodiment.

FIG. 16 is a partial cross-sectional view of the field termination structure in a region between two adjacent power semiconductor devices, according to another embodiment.

FIG. 17 is a partial cross-sectional view of the field termination structure in a region between two adjacent power semiconductor devices, according to another embodiment.

FIG. 18 is a partial top plan view of the field termination structure in a region where active areas of two adjacent power semiconductor devices and the substrate edge neighbor each other, according to an embodiment.

FIG. 19 is a corresponding cross-sectional view taken along the line labelled A-A′ in FIG. 18.

FIG. 20 is a partial top plan view of the field termination structure in a region where active areas of two adjacent power semiconductor devices and the substrate edge neighbor each other, according to another embodiment.

FIG. 21 is a partial top plan view of the field termination structure in a region where active areas of two adjacent power semiconductor devices and the substrate edge neighbor each other, according to another embodiment.

FIG. 22 is a partial cross-sectional view of the field termination structure in a region between two adjacent power semiconductor devices, according to an embodiment.

FIG. 23 is a partial cross-sectional view of the field termination structure in a region between two adjacent power semiconductor devices, according to another embodiment.

### DETAILED DESCRIPTION

The embodiments described herein provide a field termination structure for monolithically integrated power semiconductor devices. The field termination structure is interposed between adjacent power semiconductor devices and between the power semiconductor devices and the die (chip) edge. The field termination structure has two parts. The first part is designed for a bidirectional electric potential gradient during operation of the power semiconductor devices and prevents a space charge region that arises in one power semiconductor device from reaching an adjacent power semiconductor device under both directions of the bidirectional electric potential gradient. The second part is designed for a unidirectional electric potential gradient during operation of the power semiconductor devices and prevents a space charge region that arises in a power semiconductor device from reaching the edge of the semiconductor substrate under a single direction of the unidirectional electric potential gradient. For example, the second part is designed to prevent the space charge region that arises in one power semiconductor device from reaching the edge of the semiconductor substrate only under a single direction of the unidirectional electric potential gradient but not in the opposite direction.

Described next with reference to the figures are embodiments of the field termination structure.

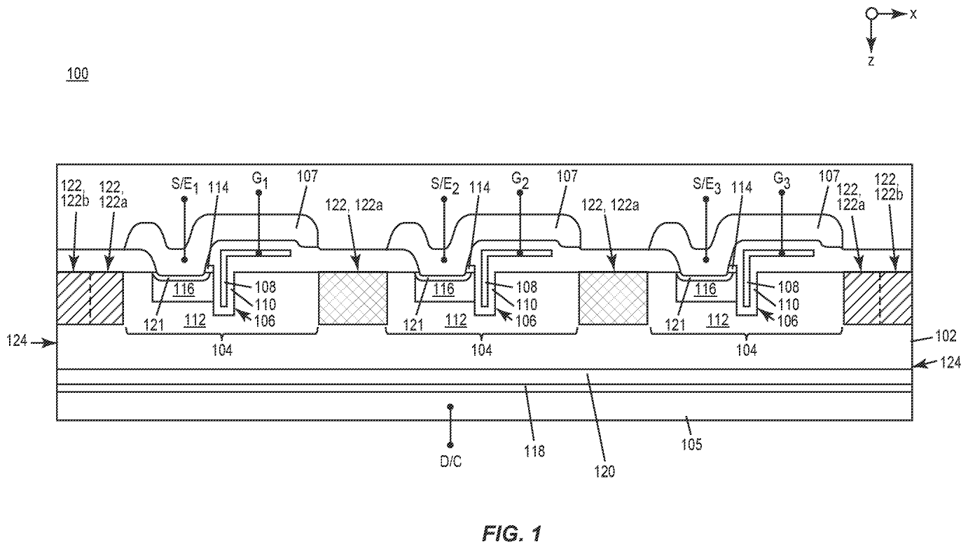

FIG. 1 illustrates a partial cross-sectional view of a semiconductor die 100. The semiconductor die 100 includes a semiconductor substrate 102. The semiconductor substrate 102 comprises one or more semiconductor materials that are used to form power semiconductor devices such as, e.g., Si or SiC power MOSFETs, IGBTs, JFETs, HEMTs, power diodes etc. In other words, a plurality of power semiconductor devices may be formed within the same semiconductor substrate 102. The plurality of power semiconductor devices may have a same operation principle, or at least some of the plurality of power semiconductor devices may have an operation principle different to each other. For example, the semiconductor substrate 102 may comprise Si, silicon carbide (SiC), germanium (Ge), silicon germanium (SiGe), gallium nitride (GaN), gallium arsenide (GaAs), and the like. The semiconductor substrate 102 may be a bulk semiconductor material or may include one or more epitaxial layers grown on a bulk semiconductor material.

Power semiconductor devices 104 are formed in the semiconductor substrate 102 and have at least one power terminal that is isolated from the other devices. Three (3) power semiconductor devices 104 are shown in FIG. 1. However, depending on the application, the semiconductor die 100 may include two (2) power semiconductor devices 104 or more than three power semiconductor devices 104.

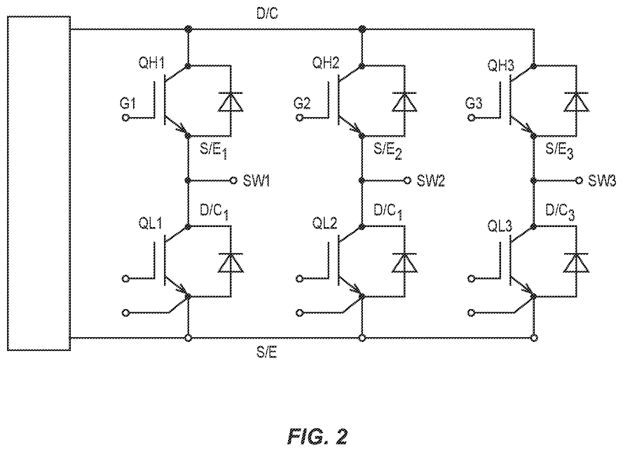

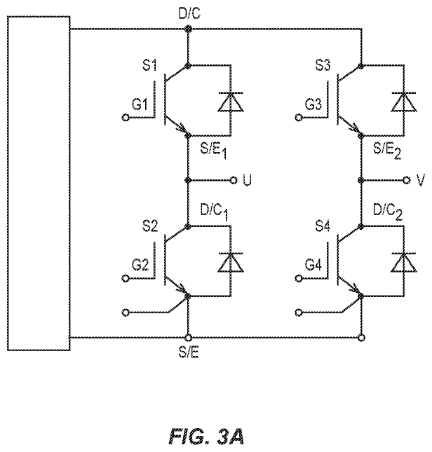

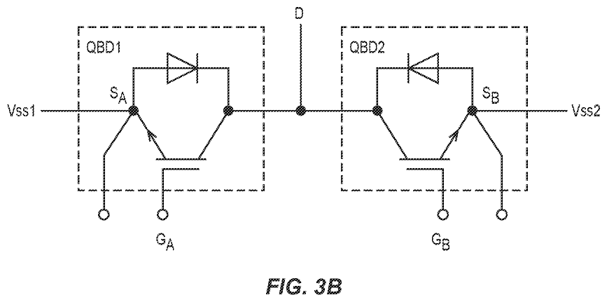

In power electronics applications, power semiconductor switches are often used in different forms of a bridge circuit such as 3-phase inverter bridge (FIG. 2), an H-bridge (FIG. 3A), or a bi-directional controllable switch (FIG. 3B). In multi-level inverter topologies such as T-type neutral-point clamped (NPC-2) topology, H6.5 topology, HERIC topology, and matrix converter topology, switches capable of controlling current flow in both positive and negative directions are required. Such switches are often referred to as bidirectional controllable switches, bidirectional switches, fully-controllable switches, or reverse-blocking switches. Bidirectional controllable switches may be constructed by using two power semiconductor switches in back-to-back series connection.

Depending on the application, the power semiconductor devices 104 may have a common drain/collector terminal ‘D/C’ formed by a backside metallization 105 and isolated source/emitter terminals ‘S/E_{N}’ formed by a frontside metallization 107, or a common source/emitter terminal ‘S/E’ formed by the backside metallization 105 and isolated drain/collector terminals ‘D/C_{N}’ formed by the frontside metallization 107, e.g., as shown in FIGS. 2 through 3B. Furthermore, one or more of the power semiconductor devices 104, e.g. all of the power semiconductor devices 104, may further comprise a isolated control terminal. Each power semiconductor device 104 includes multiple power device cells, with one cell shown in FIG. 1 for each for purpose of illustration. The power device cells 104 are electrically coupled in parallel to for the respective individual power semiconductor device 104, e.g., an IGBT, a power MOSFET, JFET, power diode, etc. Each power semiconductor device 104 may have tens, hundreds, thousands, or even more power device cells.

The power device cells shown in FIG. 1 are trench transistor cells. Each trench transistor cell includes a gate trench 106 that extends into the semiconductor substrate 102. The gate trenches 106 may be ‘stripe-shaped’ in that the gate trenches 106 may have a longest linear dimension in the y direction in FIG. 1.

The gate trenches 106 include a gate electrode 108 separated from the surrounding semiconductor substrate 102 by a gate dielectric insulating material 110. The gate electrodes 108 may be made from any suitable electrically conductive material such as but not limited to polysilicon, metal (e.g., tungsten), metal alloy, etc. The gate dielectric insulating material 110 may comprise, e.g., SiOx and may be formed by thermal oxidation and/or deposition, for example. The gate electrodes 108 are electrically connected to the gate terminal ‘G’ through, e.g., one or more metal gate runners and respective contacts/vias that are out of view in FIG. 1. Field plates (not shown) may be included in the gate trenches 106 below the gate electrodes 108 or in separate trenches (not shown) for helping to optimize the area-specific on-state resistance achievable for a given breakdown voltage, by providing charge carrier compensation. In the case of planar gate power transistor cells, the gate electrodes 108 may be formed above and insulated from the semiconductor substrate 102. The gate electrodes 110 are omitted in the case of power diode cells.

In the case of a power transistor device, the power device cells include a drift region 112 of a first conductivity type in the semiconductor substrate 102. A source/emitter region 114 of the first conductivity type is separated from the drift region 112 by a respective body region 116 of a second conductivity type. The first conductivity is n-type and the second conductivity type p-type for an n-channel device, whereas the first conductivity is p-type and the second conductivity type n-type for a p-channel device.

In the case of a Si or SiC JFET or power MOSFET, a doped region 118 common to all power device cells is a drain region 118 of the first conductivity type. The common drain region 118 adjoins the drift region 112 of the individual power device cells at the backside of the semiconductor substrate 102, with the drift region 112 separating the body region 116 of the same power device cell from the common drain region 118. Isolated source terminals ‘S/E_{N}’ are disposed at the opposite side of the die 100.

In the case of an IGBT, the common doped region 118 is instead a collector region of the second conductivity type and a buffer region 120 of the first conductivity type may adjoin the common collector region 118, with the drift region 112 separating the body region 116 of each power device cell from the buffer region 120. The buffer region 120 may be included in other device types, e.g., power MOSFETs. Isolated emitter terminals ‘S/E_{N}’ are disposed at the opposite side of the die 100.

The power device cells of each power semiconductor device 104 also may include a body contact region 121 of the second conductivity type and having a higher doping concentration than the individual body regions 116, to provide an ohmic connection to the source/emitter terminal ‘S/E_{N}’ for that power device 104. The source/emitter regions 114 are also at the same source/emitter terminal S/E_{N} for that power device 104.

Regardless of the type of power semiconductor devices 104 formed in the semiconductor substrate 102, the power semiconductor devices 104 may have a common power terminal at one side of the semiconductor die 100 and isolated individual power terminals at the opposite side of the die 100. For power transistors, the power semiconductor devices 104 may have a common drain/collector terminal ‘D/C’ and isolated source/emitter terminals ‘S/E_{N}’ or a common source/emitter terminal ‘S/E’ and isolated drain/collector terminals ‘D/C_{N}’.

In the case of the 3-phase inverter bridge example shown in FIG. 2, each leg of the inverter bridge includes a high-side transistor ‘QH_{N}’ connected in series with a low-side transistor ‘QL_{N}’ at a switching node ‘SW_{N}’. The high-side transistors QH1, QH2, QH3 have a common drain/collector terminal D/C and isolated source/emitter terminals S/E₁, S/E₂, S/E₃, whereas the low-side transistors QL1, QL2, QL3 have a common source/emitter terminal S/E and isolated drain/collector terminals D/C₁, D/C₂, D/C₃.

For the H-bridge example shown in FIG. 3A, a positive voltage is applied across terminals U and V by closing switches S1 and S4 and opening switches S2 and S3. The voltage is reversed by opening switches S1 and S4 and closing S2 and S3 switches. Switches S1 and S3 have a common drain/collector terminal D/C and isolated source/emitter terminals S/E₁, S/E₂, whereas switches S2 and S4 have a common source/emitter terminal S/E and isolated drain/collector terminals D/C₁, D/C₂. Still other types of power electronics topologies utilize devices that have a common terminal and isolated terminals, e.g., as explained above. Some or all of these devices may be formed in the same semiconductor die.

For example, the power semiconductor devices 104 included in the semiconductor die 100 may correspond to high-side switches QH1 through QH3 in FIG. 2 or switches S1 and S3 in FIG. 3A, where the devices 104 have a common drain/collector terminal D/C and isolated source/emitter terminals S/E_{N}. The low-side switches QL1 through QL3 in FIG. 2 or switches S2 and S4 in FIG. 3A instead may be monolithically integrated in the semiconductor die 100, where the devices 104 have a common source/emitter terminal S/E and isolated drain/collector terminals D/C_{N}.

FIG. 3B illustrates a bi-directional controllable switch that may be implemented by the power semiconductor devices 104 monolithically integrated in the semiconductor die 100. The main bidirectional switch has first and second gates G_{A}, G_{B}, first and second sources S_{A}, S_{B}, and a common or virtual drain D. The first source S_{A} of the main bidirectional switch is electrically connected to a first input-output terminal Vss1. The second source S_{B} of the main bidirectional switch is electrically connected to a second input-output terminal Vss2. The main bidirectional switch has four primary operational states: OFF/OFF in which both gates G_{A}, G_{B} of the main bidirectional switch are off; ON/ON in which both gates G_{A}, G_{B} of the main bidirectional switch 100 are on; ON/OFF in which the first gate G_{A} of the main bidirectional switch is on and the second gate G_{B} of the main bidirectional switch is off; and OFF/ON in which the first gate G_{A} of the main bidirectional switch is off and the second gate G_{B} of the main bidirectional switch is on. The typical operation of a bidirectional switch includes transitioning from OFF/OFF to ON/ON, ON/OFF to ON/ON, and from OFF/ON to ON/ON. The current flow direction depends on the polarity across the first and second input-output terminals Vss1, Vss2. The current flow direction can be reversed by changing the polarity. The main bidirectional switch is schematically represented by main transistors QBD1 and QBD2 in FIG. 3A. The main transistors QBD1 and QBD2 share a common drain D and have sources S_{A}, S_{B} at opposite ends of the main bidirectional switch in the case of a lateral device, and may be implemented by the power semiconductor devices 104 monolithically integrated in the semiconductor die 100.

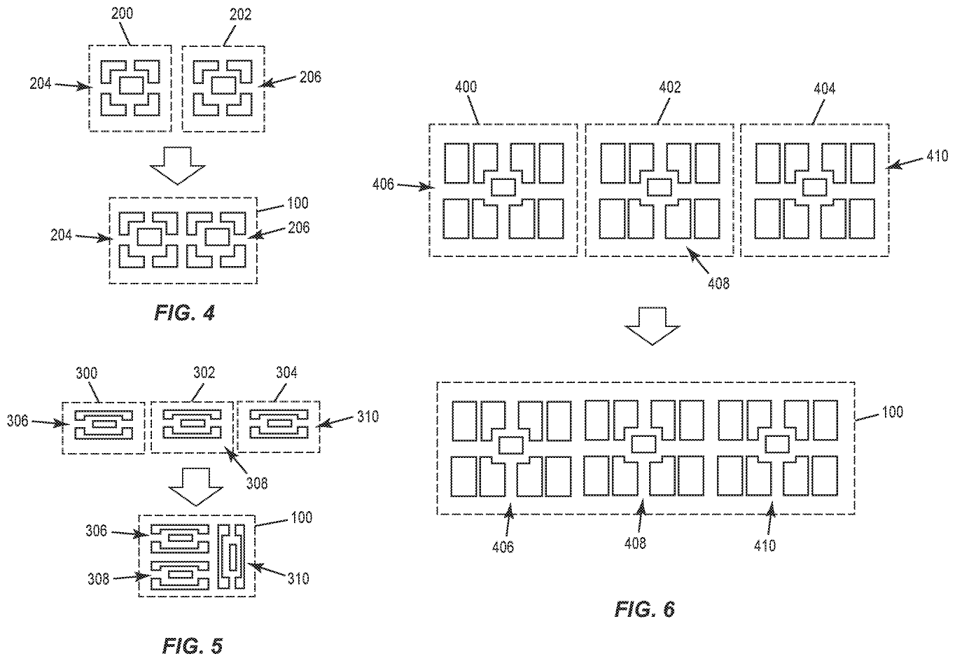

FIG. 4 illustrates a schematic comparison of a conventional half-bridge implemented using two separate transistor dies 200, 202 for the high-side and low-side switches 204, 206 of the half-bridge, and the semiconductor die 100 of FIG. 1 in which the high-side and low-side switches 204, 206 of the half-bridge may be monolithically integrated.

FIG. 5 illustrates a schematic comparison of a conventional 3-phase inverter bridge implemented using three separate smaller dies 300, 302, 304 for the legs 306, 308, 310 of the inverter, and the semiconductor die 100 of FIG. 1 in which the inverter legs 306, 308, 310 may be monolithically integrated.

FIG. 6 illustrates a schematic comparison of a conventional 3-phase inverter bridge implemented using three separate larger dies 400, 402 404 for the legs 406, 408, 410 of the inverter, and the semiconductor die 100 of FIG. 1 in which the inverter legs 406, 408, 410 may be monolithically integrated.

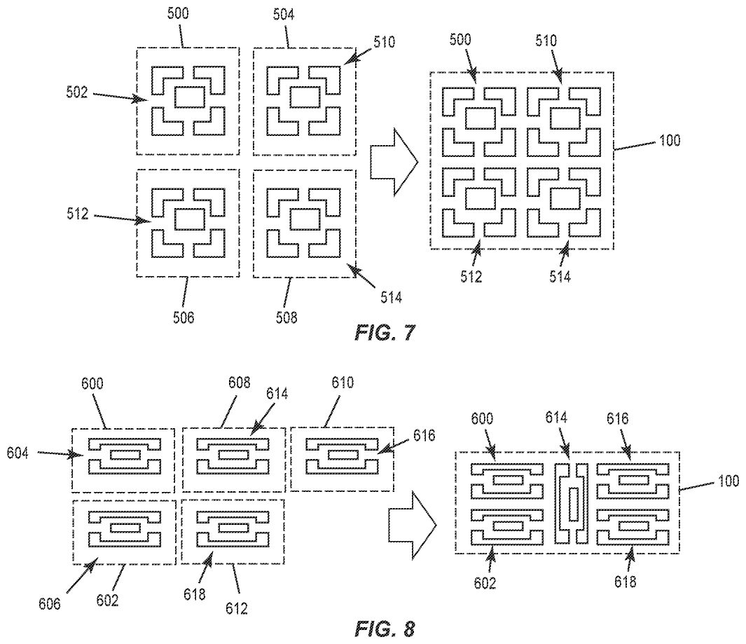

FIG. 7 illustrates a schematic comparison of a conventional boost circuit plus 3-phase inverter bridge implemented using one die 500 for the boost component 502 and three separate dies 504, 506, 508 for the legs 510, 512, 514 of the inverter, and the semiconductor die 100 of FIG. 1 in which the boost component 502 and the inverter legs 510, 512, 514 may be monolithically integrated.

FIG. 8 illustrates a schematic comparison of a conventional H-bridge plus 3-phase inverter bridge implemented using two separate dies 600, 602 for the legs 604, 606 of the H-bridge and three separate dies 608, 610, 612 for the legs 614, 616, 618 of the 3-phase inverter, and the semiconductor die 100 of FIG. 1 in which the legs 604, 606 of the H-bridge and the legs 614, 616, 618 of the 3-phase inverter may be monolithically integrated.

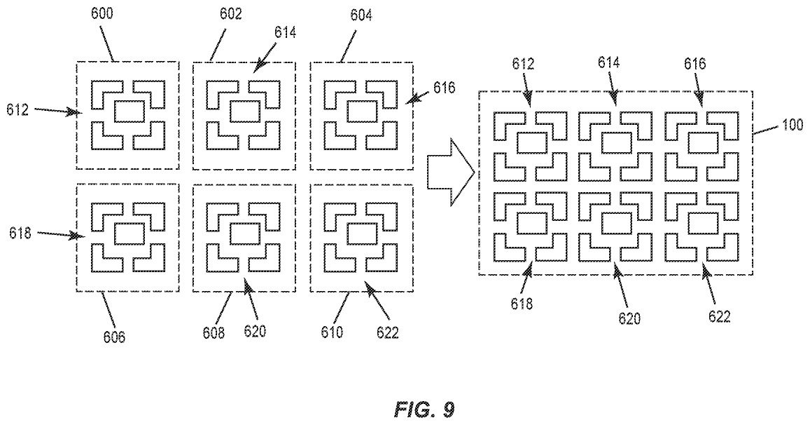

FIG. 9 illustrates a schematic comparison of a conventional dual 3-phase inverter bridge implemented using six separate dies 600, 602, 604, 606, 608, 610 for the legs 612, 614, 616, 618, 620, 622 of the respective 3-phase inverters, and the semiconductor die 100 of FIG. 1 in which the inverter legs 612, 614, 616, 618, 620, 622 may be monolithically integrated.

In each of FIGS. 4 through 9, the same circuit functionality is monolithically integrated in a single die or a subset of the dies needed for the equivalent conventional implementation. For example, the high-side transistor functionality may be monolithically integrated in one die and the low-side transistor functionality may be monolithically integrated in another die with each die having a field termination structure designed for both directions of a bidirectional electric potential gradient and a single direction of a unidirectional electric potential gradient in different regions of the dies.

As shown in FIG. 1, the semiconductor die 100 includes a field termination structure 122 designed for both directions of a bidirectional electric potential gradient and a single direction of a unidirectional electric potential gradient in different regions of the die 100. The field termination structure 122 separates individual doped region(s) of the power semiconductor devices 104 that are electrically coupled to an individual power terminal from one another and from the edge 124 of the semiconductor substrate 102. For example, in the case of power MOSFET or JFET devices, the field termination structure 122 may separate the individual source and body regions 114, 116 of the power semiconductor devices 104 that are electrically coupled to an individual source terminal S/E_{N} from one another and from the edge 124 of the semiconductor substrate 102. In the case of power IGBT devices, the field termination structure 122 may separate the individual emitter and body regions 114, 116 of the power semiconductor devices 104 that are electrically coupled to an individual emitter terminal S/E_{N} from one another and from the edge 124 of the semiconductor substrate 102.

In general, the field termination structure 122 includes a first part 122a and a second part 122b. The first part 122a of the field termination structure 122 is designed for a bidirectional electric potential gradient during operation of the power semiconductor devices 104 and prevents a space charge region that arises in one power semiconductor device 104 from reaching an adjacent power semiconductor device 104 under both directions of the bidirectional electric potential gradient. The second part 122b of the field termination structure 122 is designed for a unidirectional electric potential gradient during operation of the power semiconductor devices 104 and prevents a space charge region that arises in one power semiconductor device 104 from reaching the edge 124 of the semiconductor substrate 102 under a single direction of the unidirectional electric potential gradient.

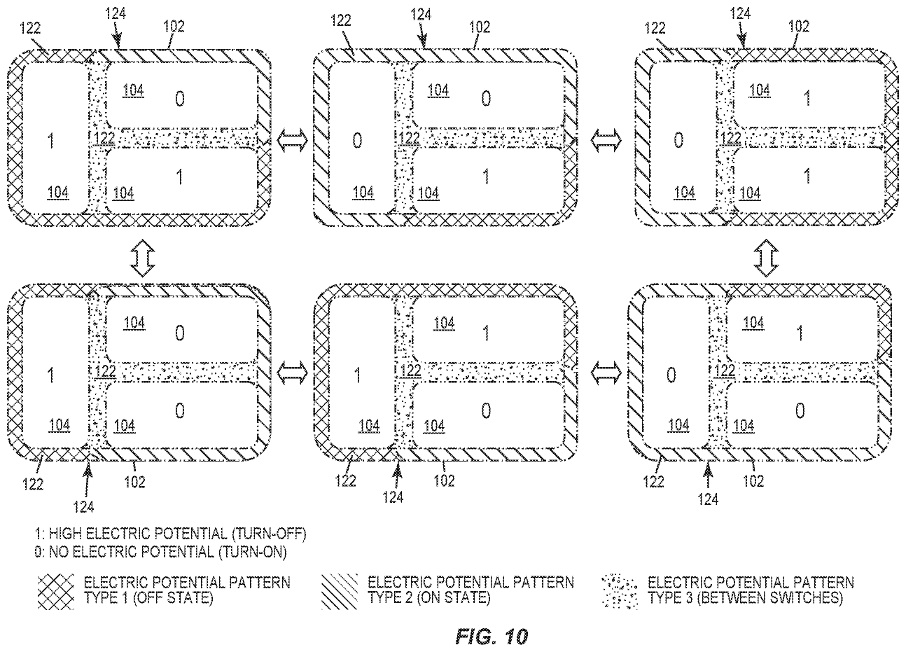

FIG. 10 is a schematic top plan view of the semiconductor die 100 during different operating states. Each power semiconductor device 104 is labelled with a ‘1’ or a ‘0’ to indicate whether that device 104 is subjected to a high electric potential or a low electric potential for each operating state of the die 100. When a power device 104 is turned on, the device 104 is conducting current and therefore not subjected to a high potential difference between front and back. When a power device 104 is turned off, a voltage potential builds up across the device power terminals (e.g., D/C and S/E) and the device 104 is subjected to a high potential difference. Either electric potential pattern 1 or electric potential pattern 2 arises in the field termination structure 122 between a power semiconductor device 104 and the edge 124 of the semiconductor substrate 102, depending on the on/off state of the device 104. The third electric potential pattern arises in the field termination structure 122 between adjacent power semiconductor devices 104.

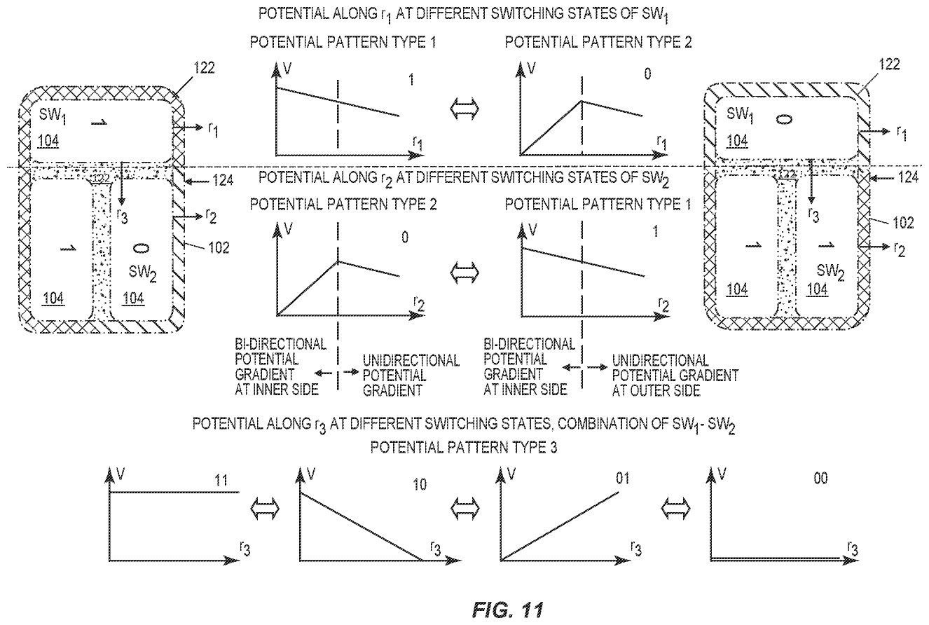

FIG. 11 shows three vectors r₁, r₂, r₃ in different parts of the field termination structure 122 and at different switching states SW₁ and SW₂. The plot diagrams included in FIG. 11 show the electric potential distribution for each vector in the indicated region of the field termination structure 122. Vector r₁ extends from the outer edge of a power semiconductor device 104 in a high potential state (1) with reference to the front side of the semiconductor substrate 102. Vector r₂ extends from the outer edge of a power semiconductor device 104 in a low potential state (0) with reference to the front side of the semiconductor substrate 102. Vector r₃ extends between two adjacent power semiconductor devices 104.

As shown in FIG. 11, vectors r₁ and r₂ both may have an inner bidirectional electric potential gradient component further from the substrate edge 124 and an outer unidirectional electric potential gradient component closer to the substrate edge 124. The inner bidirectional electric potential gradient component is negative for pattern 1 (high electric field) and positive for pattern 2 (low electric field), thus resulting in a spatial reversal of the averaged electric potential gradient. The outer unidirectional electric potential gradient component is negative for both pattern 1 (high electric field) and pattern 2 (low electric field). Vector r₃ between adjacent devices 104 has a bidirectional electric potential gradient, depending on the switching states of the adjacent devices 104.

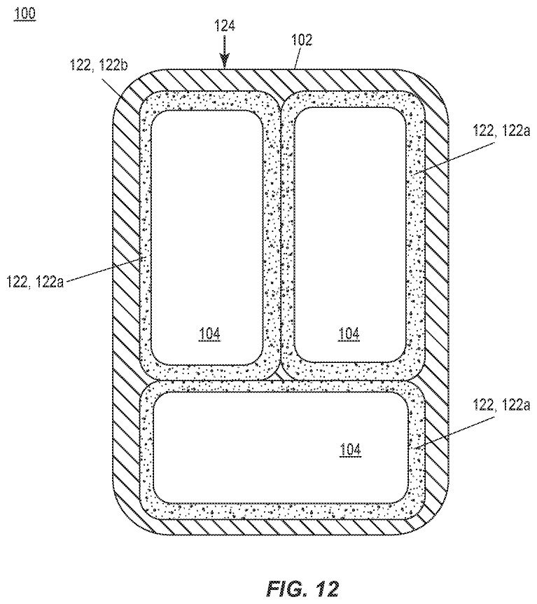

FIG. 12 is a top plan view of the semiconductor die 100 and shows the field termination structure 122 for three power semiconductor devices 104. As previously explained herein, the semiconductor die 100 may include two, three, or more power semiconductor devices 104 that share at least one common power terminal and have at least one power terminal that is isolated from the other devices.

The first part 122a of the field termination structure 122 laterally surrounds the one or more individual doped regions of each power semiconductor device 104 that are isolated from the other devices 104. In the case of JFETs or Si or SiC power MOSFETs, the drain region 118 may be common to all devices but the source and body regions 114, 116 may be isolated from the other devices 104. In the case of IGBTs, the collector region 118 may be common to all devices but the emitter and body regions 114, 116 may be isolated from the other devices 104. In the case of power diodes, the common doped region 118 at the substrate backside may be a common cathode to all devices and an anode region of each diode device may be isolated from the other anode regions. The first part 122a of the field termination structure 122 laterally surrounds the source/emitter and body regions 114, 116 and optionally the drift regions 112 and buffer regions (for IGBTs) 120 for power transistor devices, or isolated anode regions for diode devices. The first part 122a of the field termination structure 122 is designed for a bidirectional electric potential gradient during operation of the power semiconductor devices 104. The first part 122a of the field termination structure 122 prevents a space charge region that arises in one power semiconductor device 104 from reaching an adjacent power semiconductor device 104 under both directions of the bidirectional electric potential gradient.

The second part 122b of the field termination structure 122 laterally surrounds the first part 122a of the field termination structure 122 and separates the first part 122a from the edge 124 of the semiconductor substrate 102. The second part 122b of the field termination structure 122 is designed for a unidirectional electric potential gradient during operation of the power semiconductor devices 104 and prevents a space charge region that arises in one power semiconductor device 104 from reaching the edge 124 of the semiconductor substrate 102 under a single direction of the unidirectional electric potential gradient. With respect to FIG. 11, the field termination structure 122 may include just the first part 122a in the region traversed by vector r₃. For the regions traversed by vectors r₁ and r₂ in FIG. 11, the field termination structure 122 may include the first part 122a for handling the inner bidirectional gradient component further from the substrate edge 124 and the second part 122b for handling the outer unidirectional gradient component closer to the substrate edge 124.

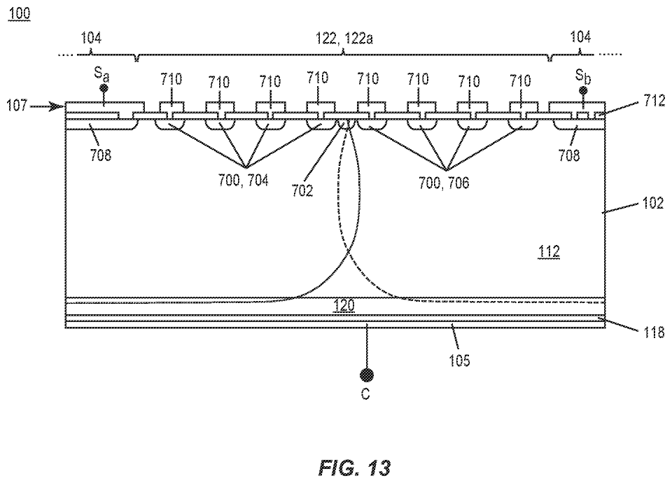

Various embodiments of the field termination structure 122 are described next in connection with FIGS. 13 through 23. These embodiments are described in the context of an IGBT but may be readily adapted to other power semiconductor device types such as power MOSFETs, JFETs, HEMTs, power diodes, etc. For example, in the case of a power MOSFET, the IGBT collector of the second conductivity type is replaced by a drain region of the first conductivity type. In the case of a power diode, the emitter/source and body regions are replaced by an anode region of the second conductivity type and the collector/drain region is replaced by a cathode region of the first conductivity type. The embodiments described next reduce die area needed for the field termination structure 122, compared to conventional field termination structures, without comprising effectiveness of the field termination functionality.

FIG. 13 is a partial cross-sectional view of the field termination structure 122 in a region between two adjacent power semiconductor devices 104, according to an embodiment. In the illustrated region, the first part 122a of the field termination structure 122 includes rings 700 of the second conductivity type encircling each power semiconductor device 104. The first part 122a of the field termination structure 122 also includes at least one ring 702 of the first conductivity type interposed between a first group 704 and a second group 706 of the rings 700 of the second conductivity type.

The first part 122a of the field termination structure 122 is designed to stop the lateral extension of a space charge region that extends outward from one power semiconductor device 104 from reaching a region 708 of the second conductivity of the adjacent power semiconductor device 104. Otherwise, a high leakage current could arise. The boundary of the space charge regions are illustrated as dashed curvilinear lines. One or both space charge regions shown in FIG. 13 may arise at the same time, depending on the on/off state of the devices 104. Field plates 710 may be disposed above the semiconductor substrate 102 and electrically coupled to the rings 700 of the second conductivity type, e.g., through openings in an interlayer dielectric 712 formed on the frontside of the semiconductor substrate 102. The field plates 710 may be electrically floating (i.e., not connected to a define potential) or electrically coupled to a potential (e.g., emitter) provided by the frontside metallization 107. The embodiment shown in FIG. 13 blocks high voltages in both directions but requires almost twice the width of a conventional edge termination structure.

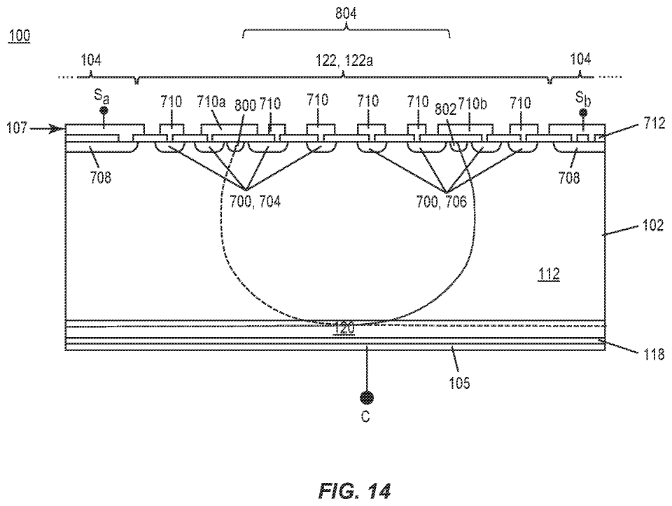

FIG. 14 is a partial cross-sectional view of the field termination structure 122 in a region between two adjacent power semiconductor devices 104, according to another embodiment. In the illustrated region, the first part 122a of the field termination structure 122 includes a first group 704 of rings 706 of the second conductivity type encircling a first one of the power semiconductor devices 104, a second group 706 of rings 700 of the second conductivity type encircling the adjacent power semiconductor device 104, a first ring 800 of the first conductivity type interposed between two rings 700 included in the first group 704 of rings 700 of the second conductivity type, and a second ring 802 of the first conductivity type interposed between two rings 700 included in the second group 706 of rings 700 of the second conductivity type. The first (left) ring 800 of the first conductivity type is designed to stop the lateral extension of a space charge region that extends outward from the adjacent (right) power semiconductor device 104 from reaching a region 708 of the second conductivity of the power semiconductor device 104. The second (right) ring 802 of the first conductivity type is designed to stop the lateral extension of a space charge region that extends outward from the adjacent (left) power semiconductor device 104 from reaching a region 708 of the second conductivity of the power semiconductor device 104. The region of the field termination structure 122 between the first and second rings 800, 802 of the first conductivity type is used in both directions, therefore area can be saved compared with the structure shown in FIG. 13. The first and second rings 800, 802 of the first conductivity type may be positioned symmetrically on opposite sides of a central region 804 of the field termination structure 122.

At rated voltage, the space charge region laterally extending from the lefthand device 104 should not be stopped by the first (left) ring 800 of the first conductivity type when the voltage is between the frontside of the left device 104 and the backside of the right device 104. Likewise, the space charge region laterally extending from the righthand device 104 should not be stopped by the second (right) ring 802 of the first conductivity type when the voltage is between the frontside of the right device 104 and the backside of the left device 104.

To satisfy these conditions, a first field plate 710a may laterally extend towards the central region 804 of the field termination structure 122 so as to at least partly extend over the first ring 800 of the first conductivity type. A second field plate 710b may laterally extend towards the central region 804 of the field termination structure 122 so as to at least partly extend over the second ring 802 of the first conductivity type. As shown in FIG. 14, the first field plate 710a may laterally extend beyond the first ring 800 of the first conductivity type in a direction of the central region 804 of the field termination structure 122 and may even partly overlap the adjacent ring 700 of the second conductivity type. Likewise, the second field plate 710b may laterally extend beyond the second ring 802 of the first conductivity type in a direction of the central region 804 of the field termination structure 122 and may even partly overlap the adjacent ring 700 of the second conductivity type. Such an arrangement of the first and second field plates 710a, 710b helps to transport the electric potential over the ring 800, 802 of the first conductivity type covered by the corresponding field plate 710a, 710b which allows the space charge region to spread further in one direction, whereas in the other direction the field plates 710, 710b assist in stopping the space charge region.

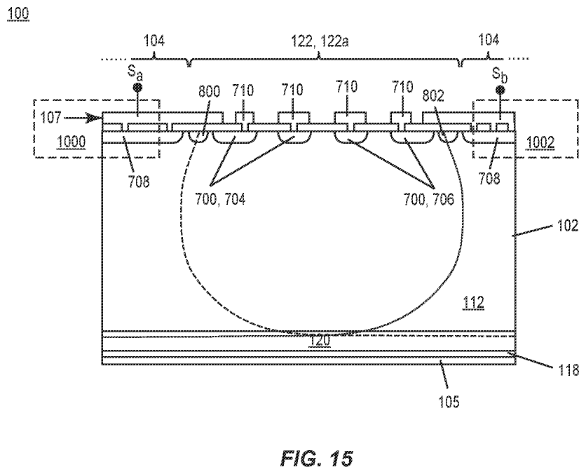

FIG. 15 is a partial cross-sectional view of the field termination structure 122 in a region between two adjacent power semiconductor devices 104, according to another embodiment. The illustrated region is more compact compared to the structure shown in FIG. 14, saving more space but eliminating redundancy. In the illustrated region, the field termination structure 122 is devoid of rings 700 of the second conductivity type between the first ring 800 of the first conductivity type and an active area 1000 of the power semiconductor device 104 that is adjacent to the first ring 800 of the first conductivity type. The field termination structure 122 also is devoid of rings 700 of the second conductivity type between the second ring 802 of the first conductivity type and an active area 1002 of the power semiconductor device 104 that is adjacent to the second ring 802 of the first conductivity type. The term ‘active area’ refers to a region of the power semiconductor devices 104 that is designed to conduct current when the power semiconductor device 104 is turned on.

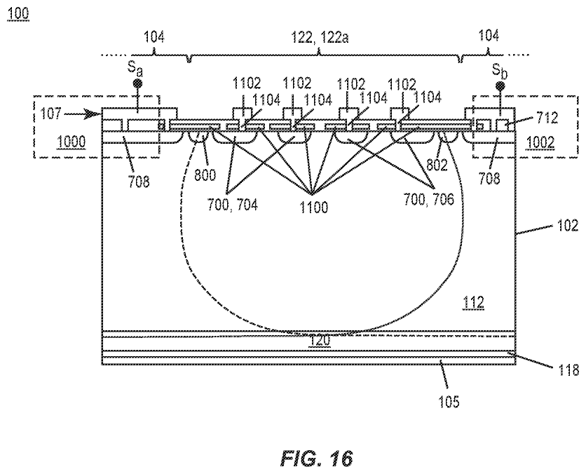

FIG. 16 is a partial cross-sectional view of the field termination structure 122 in a region between two adjacent power semiconductor devices 104, according to another embodiment. In the illustrated region, the field plates are implemented as polysilicon field plates 1100 embedded in the interlayer dielectric 712. The metal structures 1102 above the polysilicon field plates 1100 are used as a connection between the rings 700 of the second conductivity type and the polysilicon field plates 1100. Electrically conductive vias 1104 vertically extend through openings in the polysilicon field plates 1100 to the rings 700 of the second conductivity type and electrically connect the polysilicon field plates 1100 to the rings 700 of the second conductivity type.

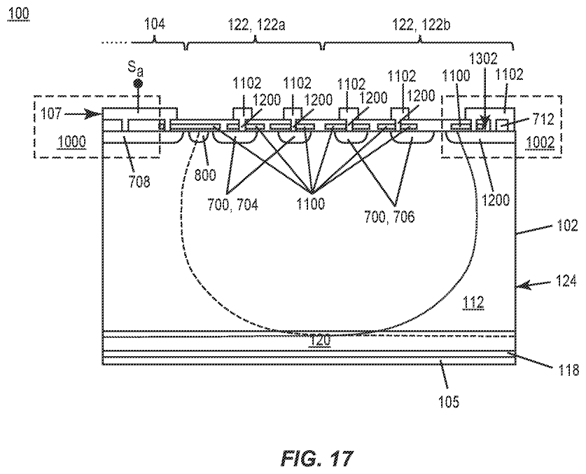

FIG. 17 is a partial cross-sectional view of the field termination structure 122 in a region between a power semiconductor device 104 and the edge 124 of the semiconductor substrate 102, according to an embodiment. In the illustrated region, the field termination structure 122 includes a first part 122a that is designed for a bidirectional electric potential gradient during operation of the power semiconductor devices 104 and that prevents a space charge region that arises in the power semiconductor device 104 from reaching an adjacent power semiconductor device 104 under both directions of the bidirectional electric potential gradient, and a second part 122b that is designed for a unidirectional electric potential gradient during operation of the power semiconductor device 104 and that prevents a space charge region that arises in the power semiconductor device 104 from reaching the edge 124 of the semiconductor substrate 102 under a single direction of the unidirectional electric potential gradient.

The second part 122b of the field termination structure 122 may include a (channel stopper) region 1200 of the first conductivity type that extends to the edge 124 of the semiconductor substrate 104. The channel stopper region 1200 improves the connection of the outermost ring 700 of the second conductivity type to the rear side potential. The channel stopper region 1200 may be spaced apart from the outermost ring 700 of the second conductivity type or may directly adjoin the outermost ring 700 of the second conductivity type. Separately or in combination, the channel stopper region 1200 may have a higher doping concentration of the first conductivity type nearer a surface 1302 of the semiconductor substrate 102 than deeper in the semiconductor substrate 102.

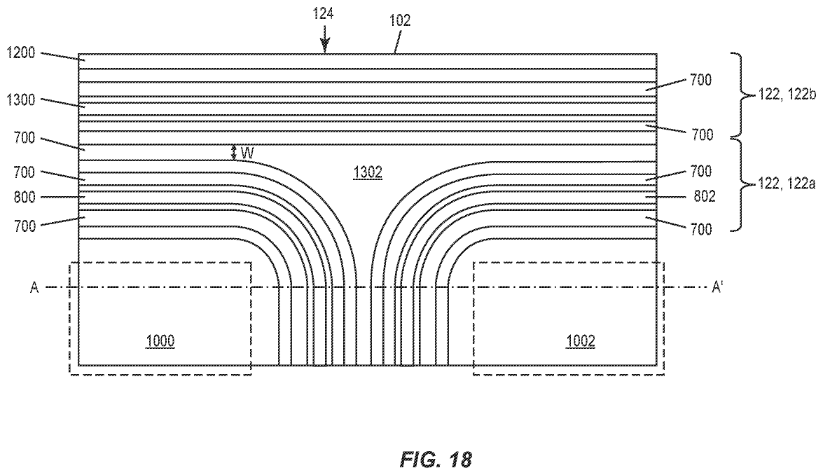

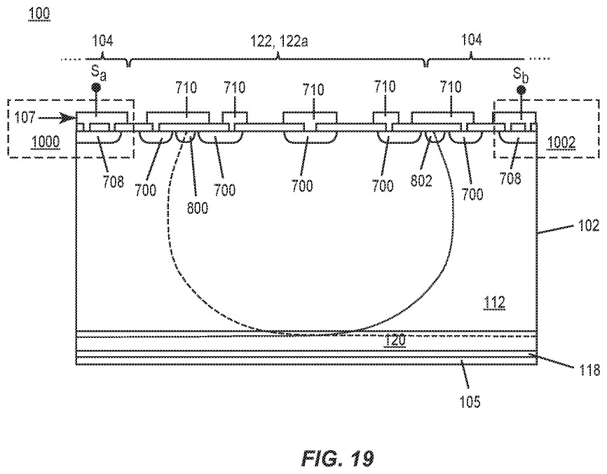

FIG. 18 is a partial top plan view of the field termination structure 122 in a region where active areas 1000, 1002 of two adjacent power semiconductor devices 104 and the substrate edge 124 neighbor each other, according to an embodiment. FIG. 19 is a corresponding cross-sectional view taken along the line labelled A-A′ in FIG. 18.

Between each power semiconductor device 104 and the edge 124 of the semiconductor substrate 102, the first part 122a of the field termination structure 122 includes at least two rings 700 of the second conductivity type encircling each power semiconductor device 104 and a ring 800, 802 of the first conductivity type interposed between the at least two rings 700 of the second conductivity type. The field termination structure 122 may include a channel stopper region 1200 of the first second conductivity type that extends to the edge 124 of the semiconductor substrate 102 and is spaced apart from or directly adjoins the outermost ring 700 of the second conductivity type. The second part 122b of the field termination structure 122 may include an additional ring 1300 of the first conductivity type that encircles all of the power semiconductor devices 104. The additional ring 1300 of the first conductivity type may be interposed between the channel stopper region 1200 and the outermost ring 700 of the second conductivity type or may be omitted from the field termination structure 122.

A ring 700 of the second conductivity type interposed between the first and second rings 800, 802 of the first conductivity type included in the first part 122a of the field termination structure 122 may have a width ‘W’ that increases in a transition region 1302 between adjacent power semiconductor devices 104 or between adjacent power semiconductor devices 104 and the edge 124 of the semiconductor substrate 102. The corresponding field plate 710/1100 disposed above the transition region 1302 may have an extended width to accommodate for the transition between the different field termination areas. Separately or in combination, an odd number of rings 700 of the second conductivity type may be interposed between the rings 800, 802 of the first conductivity type included in the first part 122a of the field termination structure 122.

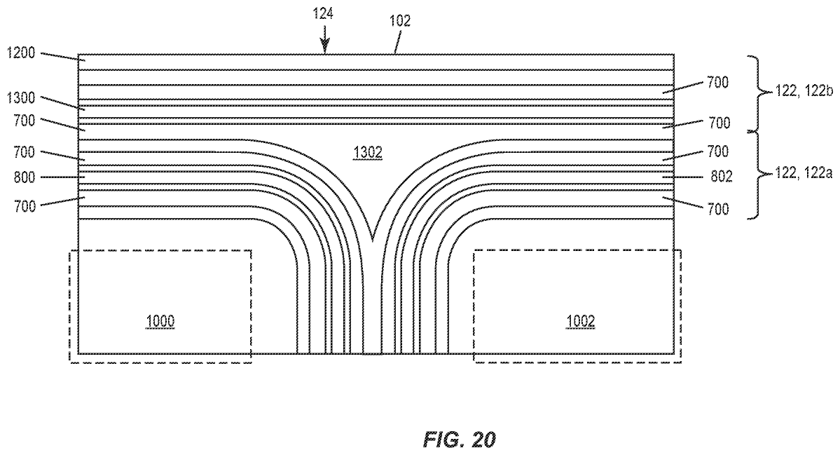

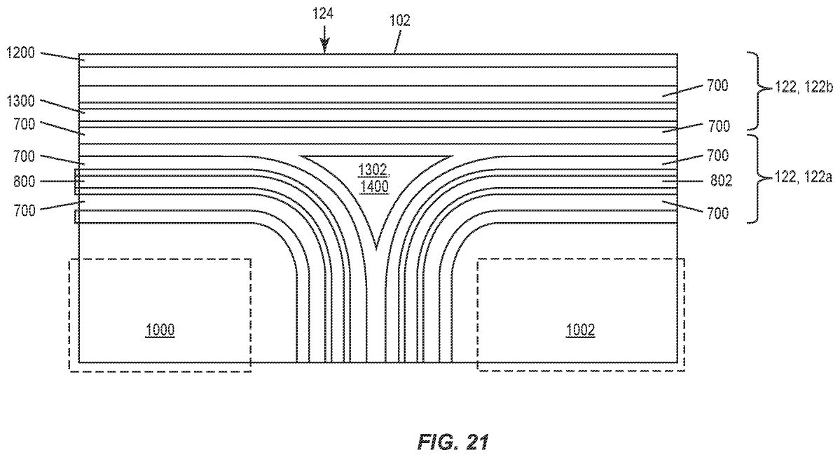

FIG. 20 is a partial top plan view of the field termination structure 122 in a region where active areas 1000, 1002 of two adjacent power semiconductor devices 104 and the substrate edge 124 neighbor each other, according to another embodiment. Between adjacent power semiconductor devices 104, the first part 122a of the field termination structure 122 includes an even number of rings 700 of the second conductivity type between the rings 800, 802 of the first conductivity type.

FIG. 21 is a partial top plan view of the field termination structure 122 in a region where active areas 1000, 1002 of two adjacent power semiconductor devices 104 and the substrate edge 124 neighbor each other, according to an embodiment. In the transition region 1302, a floating region 1400 of the second conductivity type has no electrical connection to the rings 700 of the second conductivity type.

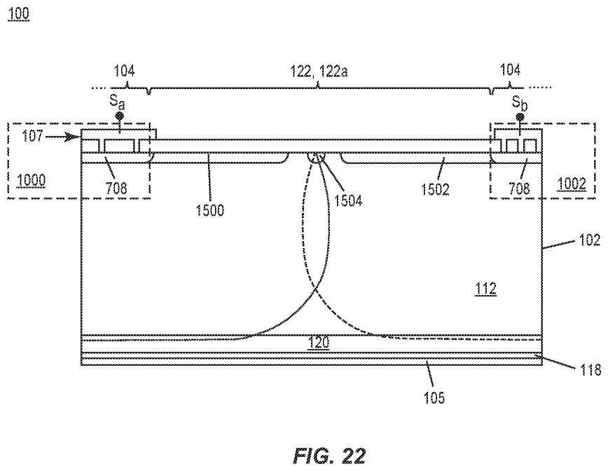

FIG. 22 is a partial cross-sectional view of the field termination structure 122 in a region between two adjacent power semiconductor devices 104, according to an embodiment. In the illustrated region, the field termination structure 122 includes a first junction termination doping region (junction termination extension or JTE) 1500 of the second conductivity type laterally extending from the active area 1000 of the first (left) power semiconductor device 104 toward the second (right) power semiconductor device 104 and a second junction termination doping region 1502 of the second conductivity type laterally extending from the active area 1002 of the second (right) power semiconductor device 104 toward the first (left) power semiconductor device 104. Each junction termination doping region 1500, 1502 is depleted to a large lateral extent during blocking and may be connected to a region 708 of the second conductivity of the adjacent power semiconductor device 104. For example, each junction termination doping region 1500, 1502 may have a doping concentration in a range of 5×10¹¹ to 5×10¹² cm⁻² for Si or 5×10¹² to 5×10¹³ cm⁻² for SiC.

The field termination structure 122 also includes a field stop region 1504 of the first conductivity type interposed between the junction termination doping regions 1500, 1502. The field stop region 1504 of the first conductivity type prevents a space charge region that arises in the first (left) power semiconductor device 104 from reaching the second junction termination doping region 1502 and prevents a space charge region that arises in the second (right) power semiconductor device 104 from reaching the first junction termination doping region 1500. Otherwise, a short could occur which would result in high leakage current. The boundaries of the space charge regions are illustrated as dashed curvilinear lines. One or both space charge regions shown in FIG. 22 may arise at the same time, depending on the on/off state of the devices 104.

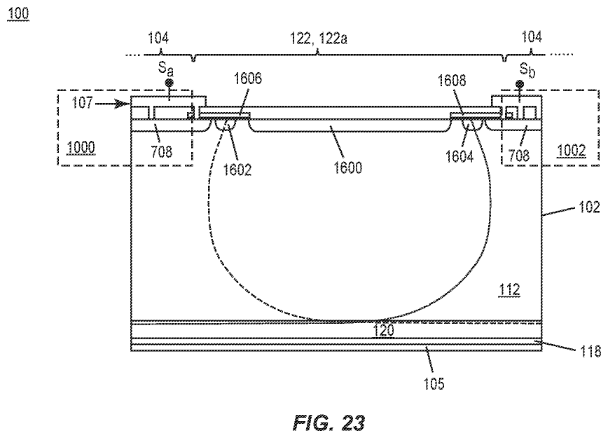

FIG. 23 is a partial cross-sectional view of the field termination structure 122 in a region between two adjacent power semiconductor devices 104, according to another embodiment. In the illustrated region, the field termination structure 122 includes a single junction termination doping (JTE) region 1600 of the second conductivity type interposed between the active area 1000 of the first (left) power semiconductor device 104 and the active area 1002 of the second (right) power semiconductor device 104, a first field stop region 1602 of the first conductivity type interposed between the active area 1000 of the first (left) power semiconductor device 104 and the junction termination doping region 1600, and a second field stop region 1604 of the first conductivity type interposed between the active area 1002 of the second (right) power semiconductor device 104 and the junction termination doping region 1600.

The first field stop region 1602 of the first conductivity type prevents a space charge region that arises in the second (right) power semiconductor device 104 from reaching the active area 1000 of the first (left) power semiconductor device 104. The second field stop region 1604 of the first conductivity type prevents a space charge region that arises in the first (left) power semiconductor device 104 from reaching the active area 1002 of the second (right) power semiconductor device 104. The embodiment illustrated in FIG. 23 uses less space than the embodiment illustrated in FIG. 22, by using a single junction termination doping region 1600 of the second conductivity type and two smaller field stop regions 1602, 1604 of the first conductivity type which separate the junction termination doping region 1600 from the outermost region 708 of the second conductivity in the active areas 1000, 10002 of the adjacent power semiconductor devices 104. A region like the junction termination doping region 1500, 1502 of the second conductivity type may be interposed between the respective active area 1002 and the corresponding field stop region 1602, 1604.

The field termination structure 122 may further include a first polysilicon or metal field plate 1606 above the semiconductor substrate 102 and covering the first field stop region 1602 of the first conductivity type and a second polysilicon or metal field plate 1608 above the semiconductor substrate 102 and covering the second field stop region 1604 of the first conductivity type. The field plates 1606, 1608 assist the action of the field stop regions 1602, 1604, as previously described herein.

Although the present disclosure is not so limited, the following numbered examples demonstrate one or more aspects of the disclosure.
Example 1. A semiconductor die, comprising: a semiconductor substrate; a plurality of power semiconductor devices formed in the semiconductor substrate and sharing one or more common doped regions that form a common power terminal at a first side of the semiconductor substrate, wherein at a second side of the semiconductor substrate opposite the first side, each power semiconductor device has an individual power terminal that is electrically coupled to one or more individual doped regions that are isolated from the other power semiconductor devices; and a field termination structure that separates the one or more individual doped regions of the power semiconductor devices from one another and from an edge of the semiconductor substrate, wherein the field termination structure comprises: a first part that is designed for a bidirectional electric potential gradient during operation of the power semiconductor devices and configured to prevent a space charge region that arises in one power semiconductor device from reaching an adjacent power semiconductor device under both directions of the bidirectional electric potential gradient; and a second part that is designed for a unidirectional electric potential gradient during operation of the power semiconductor devices and configured to prevent a space charge region that arises in one power semiconductor device from reaching an edge of the semiconductor substrate under a single direction of the unidirectional electric potential gradient.
Example 2. The semiconductor die of example 1, wherein the plurality of power semiconductor devices are IGBTs (insulated gate bipolar transistors), wherein the one or more common doped regions include a common collector region of a second conductivity type, and wherein the one or more individual doped regions of the power semiconductor devices include a body region of the second conductivity type and an emitter region a first conductivity type opposite the second conductivity type adjacent the body region.
Example 3. The semiconductor die of example 1, wherein the plurality of power semiconductor devices are power MOSFETs (metal-oxide-semiconductor field-effect transistors), wherein the one or more common doped regions include a common drain region of a first conductivity type, and wherein the one or more individual doped regions of the power semiconductor devices include a body region of a second conductivity type opposite the first conductivity type and a source region of the first conductivity type adjacent the body region.
Example 4. The semiconductor die of any of examples 1 through 3, wherein between adjacent ones of the power semiconductor devices, the field termination structure comprises: a plurality of rings of the second conductivity type encircling each power semiconductor device; and at least one ring of the first conductivity type interposed between a first group and a second group of the rings of the second conductivity type.
Example 5. The semiconductor die of example 4, further comprising field plates above the semiconductor substrate and electrically coupled to the rings of the second conductivity type.
Example 6. The semiconductor die of example 5, wherein between a power semiconductor device and the edge of the semiconductor substrate, the field termination structure further comprises: a region of the first conductivity type that extends to the edge of the semiconductor substrate and that is spaced apart from an outermost one of the rings of the second conductivity type.
Example 7. The semiconductor die of example 5, wherein between a power semiconductor device and the edge of the semiconductor substrate, the field termination structure further comprises: a region of the first conductivity type that extends to the edge of the semiconductor substrate and that directly adjoins an outermost one of the rings of the second conductivity type.
Example 8. The semiconductor die of example 5, wherein between a power semiconductor device and the edge of the semiconductor substrate, the field termination structure further comprises: a region of the first conductivity type that extends to the edge of the semiconductor substrate and that has a higher doping concentration of the first conductivity type nearer a surface of the semiconductor substrate than deeper in the semiconductor substrate.
Example 9. The semiconductor die of any of examples 1 through 8, wherein between a power semiconductor device and an edge of the semiconductor substrate, the field termination structure comprises: at least two rings of the second conductivity type encircling each power semiconductor device; and a ring of the first conductivity type interposed between the at least two rings of the second conductivity type.
Example 10. The semiconductor die of any of examples 1 through 9, wherein between adjacent ones of the power semiconductor devices, the field termination structure comprises: a first group of rings of the second conductivity type encircling a first one of the adjacent power semiconductor devices; a second group of rings of the second conductivity type encircling a second one of the adjacent power semiconductor devices; a first ring of the first conductivity type interposed between two rings included in the first group of rings of the second conductivity type; and a second ring of the first conductivity type interposed between two rings included in the second group of rings of the second conductivity type.
Example 11. The semiconductor die of example 10, further comprising field plates above the semiconductor substrate and electrically coupled to the rings of the second conductivity type.
Example 12. The semiconductor die of example 11, wherein the first and second rings of the first conductivity type are on opposite sides of a central region of the field termination structure, wherein a first one of the field plates laterally extends towards the central region so as to at least partly extend over the first ring of the first conductivity type, and wherein a second one of the field plates laterally extends towards the central region so as to at least partly extend over the second ring of the first conductivity type.
Example 13. The semiconductor die of example 12, wherein the first one of the field plates laterally extends beyond the first ring of the first conductivity type in a direction of the central region, and wherein the second one of the field plates laterally extends beyond the second ring of the first conductivity type in a direction of the central region.
Example 14. The semiconductor die of any of examples 11 through 13, wherein the field plates are polysilicon field plates.
Example 15. The semiconductor die of example 14, further comprising electrically conductive vias that vertically extend through openings in the polysilicon field plates to the rings of the second conductivity type and electrically connect the polysilicon field plates to the rings of the second conductivity type.
Example 16. The semiconductor die of any of examples 10 through 15, wherein between a power semiconductor device and an edge of the semiconductor substrate, the field termination structure further comprises: a region of the first second conductivity type that extends to the edge of the semiconductor substrate and is spaced apart from or directly adjoins an outermost one of the rings of the second conductivity type.
Example 17. The semiconductor die of any of examples 10 through 16, wherein a ring of the second conductivity type interposed between the first ring of the first conductivity type and the second ring of the first conductivity type has a width that increases in a transition region between adjacent power semiconductor devices or between adjacent power semiconductor devices and an edge of the semiconductor substrate.
Example 18. The semiconductor die of example 17, wherein the ring of the second conductivity type having the width that increases in the transition region terminates without extending between the adjacent power semiconductor devices.
Example 19. The semiconductor die of any of examples 1 through 18, wherein between adjacent first and second ones of the power semiconductor devices, the field termination structure comprises: a first junction termination doping region of a second conductivity type laterally extending from an active area of the first power semiconductor device toward the second power semiconductor device; a second junction termination doping region of the second conductivity type laterally extending from an active area of the second power semiconductor device toward the first power semiconductor device; and a field stop region of the first conductivity type interposed between the first junction termination doping region and the second junction termination doping region, the field stop region of the first conductivity type configured to prevent a space charge region that arises in the first power semiconductor device from reaching the second junction termination doping region, and prevent a space charge region that arises in the second power semiconductor device from reaching the first junction termination doping region.
Example 20. The semiconductor die of any of examples 1 through 18, wherein between adjacent first and second ones of the power semiconductor device, the field termination structure comprises: a junction termination doping region of a second conductivity type interposed between an active area of the first power semiconductor device and an active area of the second power semiconductor device; a first field stop region of the first conductivity type interposed between the active area of the first power semiconductor device and the junction termination doping region; and a second field stop region of the first conductivity type interposed between the active area of the second power semiconductor device and the junction termination doping region, wherein the first field stop region of the first conductivity type is configured to prevent a space charge region that arises in the second power semiconductor device from reaching the active area of the first power semiconductor device, wherein the second field stop region of the first conductivity type is configured to prevent a space charge region that arises in the first power semiconductor device from reaching the active area of the second power semiconductor device.
Example 21. The semiconductor die of example 20, further comprising: a first field plate above the semiconductor substrate and covering the first field stop region of the first conductivity type; and a second field plate above the semiconductor substrate and covering the second field stop region of the first conductivity type.
Example 22. A semiconductor die, comprising: a semiconductor substrate; a plurality of power semiconductor devices formed in the semiconductor substrate; and a field termination structure interposed between adjacent ones of the power semiconductor devices and between the power semiconductor devices and an edge of the semiconductor substrate, wherein the field termination structure comprises: a first part that is designed for a bidirectional electric potential gradient during operation of the power semiconductor devices and configured to prevent a space charge region that arises in one power semiconductor device from reaching an adjacent power semiconductor device under both directions of the bidirectional electric potential gradient; and a second part that is designed for a unidirectional electric potential gradient during operation of the power semiconductor devices and configured to prevent a space charge region that arises in a power semiconductor device from reaching the edge of the semiconductor substrate under a single direction of the unidirectional electric potential gradient.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor die, comprising:
a semiconductor substrate;
a plurality of power semiconductor devices formed in the semiconductor substrate and sharing one or more common doped regions that form a common power terminal at a first side of the semiconductor substrate, wherein at a second side of the semiconductor substrate opposite the first side, each power semiconductor device has an individual power terminal that is electrically coupled to one or more individual doped regions that are isolated from the other power semiconductor devices; and
a field termination structure that separates the one or more individual doped regions of the power semiconductor devices from one another and from an edge of the semiconductor substrate,
wherein the field termination structure comprises:
a first part designed for a bidirectional electric potential gradient during operation of the power semiconductor devices and configured to prevent a space charge region that arises in one power semiconductor device from reaching an adjacent power semiconductor device under both directions of the bidirectional electric potential gradient; and
a second part designed for a unidirectional electric potential gradient during operation of the power semiconductor devices and configured to prevent a space charge region that arises in one power semiconductor device from reaching an edge of the semiconductor substrate under a single direction of the unidirectional electric potential gradient.

2. The semiconductor die of claim 1, wherein the plurality of power semiconductor devices are IGBTs (insulated gate bipolar transistors), wherein the one or more common doped regions include a common collector region of a second conductivity type, and wherein the one or more individual doped regions of the power semiconductor devices include a body region of the second conductivity type and an emitter region a first conductivity type opposite the second conductivity type adjacent the body region.

3. The semiconductor die of claim 1, wherein the plurality of power semiconductor devices are power MOSFETs (metal-oxide-semiconductor field-effect transistors), wherein the one or more common doped regions include a common drain region of a first conductivity type, and wherein the one or more individual doped regions of the power semiconductor devices include a body region of a second conductivity type opposite the first conductivity type and a source region of the first conductivity type adjacent the body region.

4. The semiconductor die of claim 1, wherein between adjacent ones of the power semiconductor devices, the field termination structure comprises:
a plurality of rings of the second conductivity type encircling each power semiconductor device; and
at least one ring of the first conductivity type interposed between a first group and a second group of the rings of the second conductivity type.

5. The semiconductor die of claim 4, further comprising field plates above the semiconductor substrate and electrically coupled to the rings of the second conductivity type.

6. The semiconductor die of claim 5, wherein between a power semiconductor device and the edge of the semiconductor substrate, the field termination structure further comprises:
a region of the first conductivity type that extends to the edge of the semiconductor substrate and that is spaced apart from an outermost one of the rings of the second conductivity type.

7. The semiconductor die of claim 5, wherein between a power semiconductor device and the edge of the semiconductor substrate, the field termination structure further comprises:
a region of the first conductivity type that extends to the edge of the semiconductor substrate and that directly adjoins an outermost one of the rings of the second conductivity type.

8. The semiconductor die of claim 5, wherein between a power semiconductor device and the edge of the semiconductor substrate, the field termination structure further comprises:
a region of the first conductivity type that extends to the edge of the semiconductor substrate and that has a higher doping concentration of the first conductivity type nearer a surface of the semiconductor substrate than deeper in the semiconductor substrate.

9. The semiconductor die of claim 1, wherein between a power semiconductor device and an edge of the semiconductor substrate, the field termination structure comprises:
at least two rings of the second conductivity type encircling each power semiconductor device; and
a ring of the first conductivity type interposed between the at least two rings of the second conductivity type.

10. The semiconductor die of claim 1, wherein between adjacent ones of the power semiconductor devices, the field termination structure comprises:
a first group of rings of the second conductivity type encircling a first one of the adjacent power semiconductor devices;
a second group of rings of the second conductivity type encircling a second one of the adjacent power semiconductor devices;
a first ring of the first conductivity type interposed between two rings included in the first group of rings of the second conductivity type; and
a second ring of the first conductivity type interposed between two rings included in the second group of rings of the second conductivity type.

11. The semiconductor die of claim 10, further comprising field plates above the semiconductor substrate and electrically coupled to the rings of the second conductivity type.

12. The semiconductor die of claim 11, wherein the first and second rings of the first conductivity type are on opposite sides of a central region of the field termination structure, wherein a first one of the field plates laterally extends towards the central region so as to at least partly extend over the first ring of the first conductivity type, and wherein a second one of the field plates laterally extends towards the central region so as to at least partly extend over the second ring of the first conductivity type.

13. The semiconductor die of claim 12, wherein the first one of the field plates laterally extends beyond the first ring of the first conductivity type in a direction of the central region, and wherein the second one of the field plates laterally extends beyond the second ring of the first conductivity type in a direction of the central region.

14. The semiconductor die of claim 11, wherein the field plates are polysilicon field plates.

15. The semiconductor die of claim 14, further comprising electrically conductive vias that vertically extend through openings in the polysilicon field plates to the rings of the second conductivity type and electrically connect the polysilicon field plates to the rings of the second conductivity type.

16. The semiconductor die of claim 10, wherein between a power semiconductor device and an edge of the semiconductor substrate, the field termination structure further comprises:
a region of the first second conductivity type that extends to the edge of the semiconductor substrate and is spaced apart from or directly adjoins an outermost one of the rings of the second conductivity type.

17. The semiconductor die of claim 10, wherein a ring of the second conductivity type interposed between the first ring of the first conductivity type and the second ring of the first conductivity type has a width that increases in a transition region between adjacent power semiconductor devices or between adjacent power semiconductor devices and an edge of the semiconductor substrate.

18. The semiconductor die of claim 1, wherein between adjacent first and second ones of the power semiconductor devices, the field termination structure comprises:
a first junction termination doping region of a second conductivity type laterally extending from an active area of the first power semiconductor device toward the second power semiconductor device;
a second junction termination doping region of the second conductivity type laterally extending from an active area of the second power semiconductor device toward the first power semiconductor device; and
a field stop region of the first conductivity type interposed between the first junction termination doping region and the second junction termination doping region, the field stop region of the first conductivity type configured to prevent a space charge region that arises in the first power semiconductor device from reaching the second junction termination doping region, and prevent a space charge region that arises in the second power semiconductor device from reaching the first junction termination doping region.

19. The semiconductor die of claim 1, wherein between adjacent first and second ones of the power semiconductor devices, the field termination structure comprises:
a junction termination doping region of a second conductivity type interposed between an active area of the first power semiconductor device and an active area of the second power semiconductor device;
a first field stop region of the first conductivity type interposed between the active area of the first power semiconductor device and the junction termination doping region; and
a second field stop region of the first conductivity type interposed between the active area of the second power semiconductor device and the junction termination doping region,
wherein the first field stop region of the first conductivity type is configured to prevent a space charge region that arises in the second power semiconductor device from reaching the active area of the first power semiconductor device,
wherein the second field stop region of the first conductivity type is configured to prevent a space charge region that arises in the first power semiconductor device from reaching the active area of the second power semiconductor device.

20. The semiconductor die of claim 19, further comprising:
a first field plate above the semiconductor substrate and covering the first field stop region of the first conductivity type; and
a second field plate above the semiconductor substrate and covering the second field stop region of the first conductivity type.
